(19) United States
(12) Patent Application Publication
(10) Pub. No.: US 2025/0215317 A1
(43) Pub. Date: Jul. 3, 2025

(54) QUANTUM DOT AND PREPARATION METHOD THEREOF, AND PHOTOELECTRIC DEVICE

(71) Applicants: Guangdong Juhua Research Institute of Advanced Display, Guangzhou (CN); TCL Technology Group Corporation, Huizhou (CN)

(72) Inventor: Juan ZHOU, Guangzhou (CN)

(73) Assignees: Guangdong Juhua Research Institute of Advanced Display, Guangzhou (CN); TCL Technology Group Corporation, Huizhou (CN)

(21) Appl. No.: 18/990,526

(22) Filed: Dec. 20, 2024

(30) Foreign Application Priority Data
Dec. 29, 2023 (CN) 202311873847.6

(51) Int. Cl. C09K 11/88; B82Y 20/00; B82Y 40/00; H10F 30/222; H10K 30/10

(52) U.S. Cl. CPC C09K 11/883; H10F 30/222; H10K 30/10; B82Y 20/00; B82Y 40/00

(57) ABSTRACT

Disclosed are a quantum dot and a preparation method thereof, and a photoelectric device. The quantum dot with a core-shell structure, and in a direction of a core of the quantum dot towards an outermost shell layer of the quantum dot, mole percentages of cadmium in the core and shell layers including cadmium gradually increase. The quantum dot provided by the present disclosure might be applied to a photoelectric device, and a photoelectric performance stability of the photoelectric device might be improved.

This application claims priority to Chinese Application No. 202311873847.6, entitled “QUANTUM DOT AND PHOTOELECTRIC DEVICE COMPRISING QUANTUM DOT”, filed on Dec. 29, 2023. The entire disclosures of the above application are incorporated herein by reference.

### TECHNICAL FIELD

The present disclosure relates to a field of photoelectric technologies, and in particular to a quantum dot and a preparation method thereof, and a photoelectric device.

### BACKGROUND

A quantum dot also known as a semiconductor nanocrystal, is nanocrystal with radius less than or close to an excitonic Bohr radius, and the average particle size is usually between 1 nm and 30 nm. The quantum dot has a unique fluorescence nanoscale effect, and a luminous wavelength of the quantum dot might be regulated by changing its own size and composition. The quantum dot has advantages of narrow half-peak width of luminous spectrum, high colour purity, good light stability, wide excitation spectrum and controllable emission spectrum, thus the quantum dot has a wide application prospect in photovoltaic power generation, photoelectric display, biological probes and other technical fields.

### Technical Solution

In view of this, the present disclosure provides a quantum dot and a preparation method thereof, and a photoelectric device.

According to a first aspect, the present disclosure provides a quantum dot with a core-shell structure. In a direction of a core of the quantum dot towards an outermost shell layer of the quantum dot, a mole percentage of cadmium in the core and a mole percentage of cadmium in each shell layer including cadmium gradually increase.

According to a second aspect, the present disclosure provides a method for preparing a quantum dot including:
S1. providing a cationic precursor which is a solution including a zinc source and a cadmium source, introducing an inert gas at room temperature to expel air, and heating the cationic precursor to a temperature ranged between 125° C. and 180° C. for 30 minutes˜90 minutes to obtain a basic solution, after the air is completely expelled;
S2. heating the basic solution to a reaction temperature, injecting an anionic precursor into the basic solution, and ripening to obtain a core;
S3. forming multiple shell layers sequentially on a surface of the core to obtain a reaction liquid including the quantum dot;
the quantum dot with a core-shell structure, and in a direction of the core of the quantum dot towards an outermost shell layer of the quantum dot, a mole percentage of cadmium in the core and a mole percentage of cadmium in each shell layer including cadmium gradually increase.

According to a third aspect, the present disclosure provides a photoelectric device including:
an anode;
a cathode;
multiple functional layers, between the anode and the cathode, and a material of one of the multiple functional layers includes a quantum dot with a core-shell structure;
in a direction of a core of the quantum dot towards an outermost shell layer of the quantum dot, a mole percentage of cadmium in the core and a mole percentage of cadmium in each shell layer including cadmium gradually increase.

The quantum dot provided by the present disclosure might be applied to a photoelectric device, and a photoelectric performance stability of the photoelectric device might be improved.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings might be obtained based on these drawings.

FIG. 1 is a schematic diagram of a first photoelectric device according to an embodiment of the present disclosure.

FIG. 2 is a schematic diagram of a second photoelectric device according to an embodiment of the present disclosure.

FIG. 3 is a photoluminescence spectroscopy of the quantum dot according to Example 1.

FIG. 4 is a photoluminescence spectroscopy of the quantum dot according to Example 2.

FIG. 5 is an electroluminescence spectroscopy of a photoelectric device in a first state and a second state according to Example 1.

FIG. 6 is an electroluminescence spectroscopy of a photoelectric device in a first state and a second state according to Example 2.

FIG. 7 is an electroluminescence spectroscopy of a photoelectric device in a first state and a second state according to Example 3.

FIG. 8 is an electroluminescence spectroscopy of a photoelectric device in a first state and a second state according to Comparative Example 2.

FIG. 9 is a flowchart of a method for preparing a quantum dot according to an embodiment of the present disclosure.

### DETAILED DESCRIPTION

Technical solutions in embodiments of the present disclosure will be clearly and completely described below in conjunction with drawings of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Unless otherwise defined, all professional and scientific terms used herein have same meanings as those familiar to those skilled in the art. Furthermore, any method or any material similar or equivalent to that described might be used in the present disclosure. A preferred embodiment and a preferred material described herein are for illustrative purposes only, but are not intended to limit contents of the present disclosure.

An order of description of the following embodiments is not intended to limit a preferred order of the embodiments.

Each embodiment of the present disclosure may be presented in a form of range. It should be understood that a description in the form of range is merely for convenience and brevity, and should not be construed as a limitation on the scope of the disclosure.

Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

In the present disclosure, “including” refers to “including but not limited to”.

In the present disclosure, “at least one” refers to one or more, and “more” in the “one or more” refers to two or more. “one or more”, “at least one of the followings”, or similar expressions thereof refer to any combination of items listed, including any combination of a singular item or multiple items. For example, “at least one of a, b, or c”, or “at least one of a, b, and c”, may each represent: a, b, c, a-b (i.e., a and b), a-c, b-c, or a-b-c, wherein a, b, and c may be single or plural.

In the present disclosure, a description of “the A layer is formed on a side of the B layer” or “the A layer is formed on a side of the B layer away from the C layer” may mean that the A layer is directly formed on the side of the B layer or the side of the B layer away from the C layer, that is, the A layer is in contact with the B layer. It may also mean that the A layer is indirectly formed on the side of the B layer or the side of the B layer away from the C layer, that is, another film layer may be formed between the A layer and the B layer.

In the present disclosure, “and/or” is used to describe an association of associated objects, and means that there may be three relationships, for example, “A and/or B” may refer to three cases: a first case refers to the presence of A alone. A second case refers to the presence of both A and B. A third case refers to the presence of B alone, where A and B may be singular or plural.

In the present disclosure, “particle size” refers to a diameter of a nanoparticle.

When describing a structural composition of a quantum dot in the present disclosure, each layer is arranged in an order from a core of the quantum dot to an outermost shell layer of the quantum dot. Taking the quantum dot of ZnₓCd₍₁₋ₓ₎A/ZnₜCd₍₁₋ₜ₎D/Zn_{y}Cd_{(1-y)}E/ZnD as an example, ZnₓCd₍₁₋ₓ₎A represents a component of the core of the quantum dot, ZnₜCd₍₁₋ₜ₎D represents a component of a first shell layer of the quantum dot, Zn_{y}Cd_{(1-y)}E represents a component of a second shell layer of the quantum dot, and ZnD represents a component of a third shell layer, wherein “x” represents a molar percentage of zinc in the first shell layer, “1-t” represents a molar percentage of cadmium in the first shell layer, “y” represents a molar percentage of zinc in the second shell layer, and “1-y” represents a molar percentage of cadmium in the second shell layer.

Applicants have found that a general formula of a quantum dot including shell layers with the trap structure is Znₓ₀Cd₍₁₋ₓ₀₎Se/ZnD/Zn_{y0}Cd_{(1-y0)}E/ZnD, where x0 ranges from 0.6 to 0.8, y0 ranges from 0.35 to 0.95, and D is selected from S or Se. When the quantum dot including shell layers with the trap structure is applied to the quantum dot light-emitting diode, excitons are easily recombined at the shell layers with the trap structure to generate a long wavelength light during a lifetime aging of the quantum dot light emitting diode. As cadmium ions in the Znₓ₀Cd₍₁₋ₓ₀₎Se or cadmium ions in the Zn_{y0}Cd_{(1-y0)}E migrate to other shell layers, a band gap of the quantum dot may become wider, a trap characteristics of the shell layers may disappear, and a long-wavelength luminescence may weaken, resulting in a certain range of blue shift in a luminescence wavelength of the quantum dot light-emitting diode, especially for a blue quantum dot light emitting diode, the blue shift in the luminescence wavelength is more serious.

Accordingly, an embodiment of the present disclosure provides a quantum dot with a core-shell structure. In a direction from the core of the quantum dot towards the outermost shell layer, mole percentages of cadmium in the core and shell layers including cadmium gradually increase. By applying the quantum dot to a photoelectric device, a photoelectric performance stability of the photoelectric device might be improved.

In some embodiments, the shell layers of the quantum dot include a first shell layer, a second shell layer and a third shell layer arranged sequentially, the first shell layer is closer to the core of the quantum dot than the third shell layer, the core of the quantum dot includes cadmium, and at least one of the first shell layer, the second shell layer, and the third shell layer includes cadmium. In a radial direction of the core of the quantum dot toward the third shell layer, mole percentages of cadmium in the core and shell layers including cadmium gradually increase, thereby reducing a migration amount of cadmium in the core and intermediate shell layers to the outermost shell layer.

In some embodiments, a material of the core of the quantum dot is ZnₓCd₍₁₋ₓ₎A, a material of the first shell layer is ZnD or ZnₜCd₍₁₋ₜ₎D, a material of the second shell layer is Zn_{y}Cd_{(1-y)}E, and a material of the third shell layer is ZnG or ZnₘCd₍₁₋ₘ₎G. Each of A, D and G is independently selected from Se or S, and x>t>y>m.

In some embodiments, the structural composition of the quantum dot is ZnₓCd₍₁₋ₓ₎A/ZnₜCd₍₁₋ₜ₎D/Zn_{y}Cd_{(1-y)}E/ZnG; x ranges from 0.8 to 0.95, for example, x is selected from 0.8, 0.83, 0.85, 0.88, 0.9, 0.92, 0.95, or a value between any two thereof; t ranges from 0.62 to 0.8, for example, t is selected from 0.62, 0.65, 0.67, 0.7, 0.72, 0.75, 0.77, 0.8, or a value between any two thereof, preferably, t ranges from 0.65 to 0.76; y ranges from 0.4 to 0.6, for example, y is selected from 0.4, 0.43, 0.45, 0.5, 0.55, 0.58, 0.6, or a value between any two thereof.

In order to further reduce the migration amount of cadmium in the core and intermediate shell layers to the outermost shell layer, in some embodiments, the shell layers of the quantum dot further include an auxiliary shell layer disposed between the core of the quantum dot and the first shell layer. The auxiliary shell layer does not include cadmium, or the auxiliary shell layer includes cadmium, and the mole percentage of cadmium in the auxiliary shell layer is higher than the mole percentage of cadmium in the core of the quantum.

In order to improve an electron confinement capability and/or a hole confinement capability of the quantum dot, in some embodiments, a material of the auxiliary shell layer is selected from ZnR or Zn_{z}Cd_{(1-z)}R, where R is selected from Se or S, and z ranges from 0.62 to 0.8, for example, z is selected from 0.62, 0.65, 0.67, 0.7, 0.72, 0.75, 0.77, 0.8, or a value between any two thereof.

In some embodiments, an average thickness of the auxiliary shell layer ranges from 0.8 nm to 1.5 nm, such as 0.8 nm, 1.0 nm, 1.2 nm, 1.5 nm, or a value between any two thereof.

In some embodiments, the structural composition of the quantum dot is ZnₓCd₍₁₋ₓ₎A/ZnR/ZnD/Zn_{y}Cd_{(1-y)}E/ZnG, where x ranges from 0.8 to 0.95, for example, x is selected from 0.8, 0.83, 0.85, 0.88, 0.9, 0.92, 0.95, or a value between any two thereof; y ranges from 0.4 to 0.6, for example, y is selected from 0.4, 0.43, 0.45, 0.5, 0.55, 0.58, 0.6, or a value between any two thereof.

In other embodiments, the structural composition of the quantum dot is ZnₓCd₍₁₋ₓ₎A/ZnR/ZnₜCd₍₁₋ₜ₎D/Zn_{y}Cd_{(1-y)}E/ZnG, where x ranges from 0.8 to 0.95, for example, x is selected from 0.8, 0.83, 0.85, 0.88, 0.9, 0.92, 0.95, or a value between any two thereof; t ranges from 0.62 to 0.8, preferably, t ranges from 0.75 to 0.8, for example, t is selected from 0.62, 0.65, 0.67, 0.7, 0.72, 0.75, 0.77, 0.8, or a value between any two thereof; y ranges from 0.4 to 0.6, for example, y is selected from 0.4, 0.43, 0.45, 0.5, 0.55, 0.58, 0.6, or a value between any two thereof.

In other embodiments, the structural composition of the quantum dot is ZnₓCd₍₁₋ₓ₎A/Zn_{z}Cd_{(1-z)}R/ZnD/Zn_{y}Cd_{(1-y)}E/ZnG, where x ranges from 0.8 to 0.95, for example, x is selected from 0.8, 0.83, 0.85, 0.88, 0.9, 0.92, 0.95, or a value between any two thereof; z ranges from 0.62 to 0.8, preferably, z ranges from 0.62 to 0.7, for example, z is selected from 0.62, 0.65, 0.67, 0.7, or a value between any two thereof; y ranges from 0.4 to 0.6, for example, y is selected from 0.4, 0.43, 0.45, 0.5, 0.55, 0.58, 0.6, or a value between any two thereof.

In other embodiments, the structural composition of the quantum dot is ZnₓCd₍₁₋ₓ₎A/Zn_{z}Cd_{(1-z)}R/ZnₜCd₍₁₋ₜ₎D/Zn_{y}Cd_{(1-y)}E/ZnG, where x ranges from 0.8 to 0.95, z ranges from 0.62 to 0.8, t ranges from 0.62 to 0.8, and y ranges from 0.4 to 0.6; preferably, z ranges from 0.75 to 0.8, and t ranges from 0.62 to 0.7.

In some embodiments, an average particle size of the quantum dot ranges from 6 nm to 10 nm, such as 6 nm, 7 nm, 8 nm, 9 nm, 10 nm, or a value between any two thereof. An average particle size of the core of the quantum dot ranges from 3 nm to 4.5 nm. An average thickness of the first shell layer ranges from 0.8 nm to 1.5 nm, such as 0.8 nm, 0.9 nm, 1 nm, 1.1 nm, 1.2 nm, 1.3 nm, 1.4 nm, 1.5 nm, or a value between any two thereof. An average thickness of the second shell layer ranges from 0.3 nm to 0.5 nm, such as 0.3 nm, 0.4 nm, 0.5 nm, or a value between any two thereof. An average thickness of the third shell layer ranges from 1.1 nm to 2 nm, such as 1.1 nm, 1.2 nm, 1.3 nm, 1.4 nm, 1.5 nm, 1.6 nm, 1.7 nm, 1.8 nm, 1.9 nm, 2 nm, or a value between any two thereof.

It should be noted that a surface of the quantum dot might also be attached with a ligand. The ligand may be a common ligand in the field, including but not limited to one or more of a C1˜C30 aliphatic carboxylic acid ligand, a C6˜C30 aromatic carboxylic acid ligand, a C1˜C30 aliphatic thiol ligand, a C6˜C30 aromatic thiol ligand, a C1˜C30 aliphatic amine ligand, a C6˜C30 aromatic amine ligand, a C1˜C30 aliphatic phosphine ligand, a C6˜C30 aromatic phosphine ligand, a C6˜C30 aromatic phosphate ester ligand, and a halogen ligand.

The C1˜C30 aliphatic carboxylic acid ligand includes but not limited to one or more of octanoic acid, nonanoic acid, decanoic acid, undecanoic acid, dodecanoic acid, tetradecanoic acid, hexadecanoic acid, octadecanoic acid, eicosanoic acid, tetracosanoic acid, hexacosanoic acid, oleic acid, linoleic acid, arachidic acid, arachidonic acid, erucic acid and docosahexaenoic acid. The C6˜C30 aromatic carboxylic acid ligand includes but not limited to one or more of benzoic acid, bibenzoic acid, and 1-naphthoic acid. The C1˜C30 aliphatic thiol ligand includes but not limited to one or more of hexanethiol, octanethiol, nonanethiol, decanethiol, undecanethiol, dodecanethiol, hexadecanethiol, and octadecanethiol. The C6˜C30 aromatic thiol ligand includes but not limited to one or more of thiophenol, triphenylmethyl mercaptan, and p-terphenyl-4,4″-dithiol. The C1˜C30 aliphatic amine ligand includes but not limited to one or more of hexylamine, octylamine, dioctylamine, trioctylamine, nonylamine, decylamine, dodecylamine, tridecylamine, tetradecylamine, pentadecylamine, hexadecylamine, heptadecylamine, octadecylamine, and oleylamine. The C6˜C30 aromatic amine ligand includes but not limited to one or more of aniline, aprindine, 4-octylaniline, and benzidine. The aliphatic phosphine ligand includes but not limited to one or more of trimethylphosphine, triethylphosphine, tripropylphosphine, tributylphosphine, trihexylphosphine, trioctylphosphine, tridecylphosphine, tributylphosphine oxide, trihexylphosphine oxide, trioctylphosphine oxide, and tridecylphosphine oxide. The C6˜C30 aromatic phosphine ligand includes but not limited to one or more of bis[2-(diphenylphosphino) ethyl]phenylphosphine and triphenylphosphine oxide. The C6˜C30 aromatic phosphate ester ligand includes but not limited to one or more of p-xylylenediphosphonic acid tetraethyl ester and diphenylphosphinic acid ethyl ester. The halogen ligand includes but not limited to one or more of —Cl, —F, —I, and —Br.

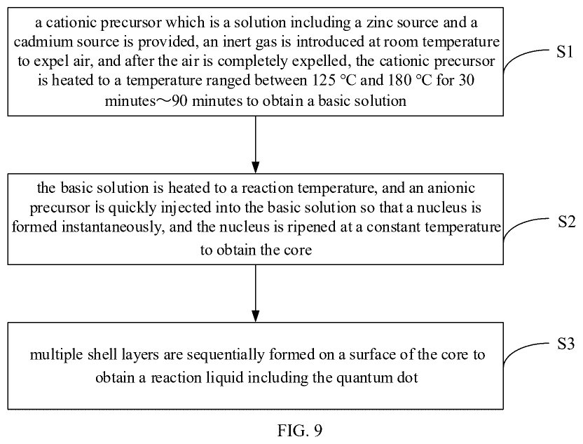

It might be understood that the quantum dot described above may be synthesized by a conventional thermal injection method. For example, referring to FIG. 9, a method for preparing the quantum dot includes steps S1˜S3.

In step S1, a cationic precursor which is a solution including a zinc source and a cadmium source is provided, an inert gas is introduced at room temperature to expel air, and after the air is completely expelled, the cationic precursor is heated to a temperature ranged between 125° C. and 180° C. for 30 minutes˜90 minutes to obtain a basic solution. The cationic precursor is contained in a container.

In step S2, the basic solution is heated to a reaction temperature, and an anionic precursor is quickly injected into the basic solution so that a nucleus is formed instantaneously, and the nucleus is ripened at a constant temperature to obtain the core.

In step S3, multiple shell layers are sequentially formed on a surface of the core to obtain a reaction liquid including the quantum dot.

Specifically, in step S1, the zinc source includes but not limited to one or more of zinc oleate, zinc stearate, zinc dodecanoate, zinc tetradecanoate, zinc hexadecanoate, zinc palmitate, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, and zinc sulfate. The cadmium source includes but not limited to one or more of cadmium oxide, cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

In step S1, a solvent of the cationic precursor includes but not limited to one or more of 1-octadecene, paraffin oil, diphenyl ether, dioctyl ether, oleic acid, stearic acid, palmitic acid, and olive oil. For example, the solvent of the cationic precursor consists of oleic acid and 1-octadecene. In order to improve a synthesis yield of the quantum dot and improve a mixing efficiency of the cationic precursor and the anionic precursor, in some embodiments, a volume ratio of oleic acid to 1-octadecene is 1:(1˜5).

In order to obtain a blue quantum dot, in some embodiments, a molar ratio of zinc to cadmium in the cationic precursor is 100:(5˜20).

In order to both improve the synthesis yield of the quantum dot and a solution processing performance of the cationic precursor, in some embodiments, a concentration of zinc in the cationic precursor ranges from 0.05 mol/L to 1 mol/L.

The inert gas includes but not limited to one or more of nitrogen, argon, helium, neon, krypton, and xenon. A flow rate of the inert gas ranges from 50 mL/minute to 300 mL/minute, and for example, the time of expelling air ranges from 10 minutes to 30 minutes.

In step S1, the anionic precursor may be a selenium precursor and/or a sulfur precursor. The selenium precursor is selected from at least one of Se-TOP, Se-TBP, Se-TPP, Se-ODE, Se-OA, Se-ODA, Se-TOA, Se-ODPA, Se-OLA, Se-OCA, and Se-DPP. The sulfur precursor is selected from at least one of S-TOP, S-TBP, S-TPP, S-ODE, S-OA, S-ODA, S-TOA, S-ODPA, S-OLA, S-OCA, S-DPP, mercaptopropylsilane, and alkyl mercaptans.

Taking S-TOP as an example, a method for preparing S-TOP includes steps S11˜S12.

In step S11, a container containing sulfur powder and trioctylphosphine (TOP) is provided, and then an inert gas is introduced at room temperature to expel air.

In step S12, after the air is completely expelled, the sulfur powder and trioctylphosphine are heated to a temperature ranged from 25° C. to 80° C. and are stirred at a constant temperature until the sulfur powder is completely dispersed to obtain a S-TOP solution. A concentration of sulfur in the S-TOP solution ranges from 0.1 mol/L to 2 mol/L.

For example, a speed of injecting the anionic precursor ranges from 1 mmol/minute to 5 mmol/minute.

In order to improve a nucleation rate of the quantum dot and a crystallinity of the quantum dot, thereby improving optical properties of the quantum dot, in some embodiments, the reaction temperature ranges from 250° C. to 315° C., such as 250° C., 260° C., 270° C., 280° C., 290° C., 315° C., or a value between any two thereof.

In order to further improve optical properties of the quantum dot, in some embodiments, a molar ratio of anions in the anion precursor injected into the basic solution to cadmium ions in the basic solution is 10:(0.5˜8).

In order to further improve a synthesis rate and optical properties of the quantum dot, in some embodiments, the ripening time ranges from 10 minutes to 60 minutes.

In step S3, in order to improve the quality of shell layers, in a process of preparing multiple shell layers, for example, a speed of injecting the anionic precursor ranges from 1 mmol/minute to 5 mmol/minute.

In order to improve an ability of the shell layers of the quantum dot to bound excitons in the core and reduce a defect density of the quantum dot, thereby improving a quantum yield of the quantum dot, in some embodiments, a molar ratio of anions in the shell layers to anions in the core is 1:(0.5˜3).

In order to improve a purity of the quantum dot, after the step S3, a reaction product including the quantum dot may be separated and purified by a conventional method to obtain a purified quantum dot. For example, a purification method includes steps S21˜S24.

In step S21, the reaction product including the quantum dot is transferred to a centrifuge tube, and n-hexane and ethanol are added to the reaction product to obtain a first mixture, then the first mixture is centrifuged at 10000 r/min for 5 minutes, a precipitate at the bottom of the centrifuge tube is collected to obtain a first precipitate. A volume ratio of the reaction product to n-hexane is 1:1, and a volume ratio of the reaction product to ethanol is 1:0.8,

In step S22, the first precipitate is completely dispersed with n-hexane and then is centrifuged at 5000 r/min for 5 minutes, and a supernatant is collected.

In step S23, ethanol is added to the supernatant to obtain a second mixture, then the second mixture is centrifuged at 10000 r/min for 5 minutes, and the bottom precipitate of the centrifuge tube is collected to obtain a second precipitate. A volume ratio of the supernatant to ethanol is 1:0.5,

In step S24, the second precipitate is redispersed in n-hexane to obtain a dispersion, and the dispersion is subjected to a vacuum drying treatment at room temperature to obtain a purified quantum dot.

It should be noted that a quantum dot material generally improves the ability to bound excitons through a core-shell structure. Under an ideal condition, a shell material with a wide bandgap may effectively bound excitons in the core and prevent excitons from delocalizing to the surface of the quantum dot.

At present, when a quantum dot as a light-emitting material in a quantum dot light-emitting diode, and shell layers of the quantum dot have a trap structure. On the one hand, excitons may be bounded to a core of the quantum dot and a shell with a lower energy band in the trap structure, so that more charge carriers might be provided to the core of the quantum dot during a working process of the quantum dot light-emitting diode, and a composite luminous efficiency of the quantum dot might be improved, moreover, a device efficiency of the quantum dot light-emitting diode might be improved; on the other hand, the shell layers with the trap structure might increase an accumulation of the charge carriers to improve a valence band, thereby reducing an energy barrier between a hole functional layer and an active layer and promoting hole injection, which is conducive to improving a problem that an electron injection level of the quantum dot light-emitting diode is much higher than a hole injection level.

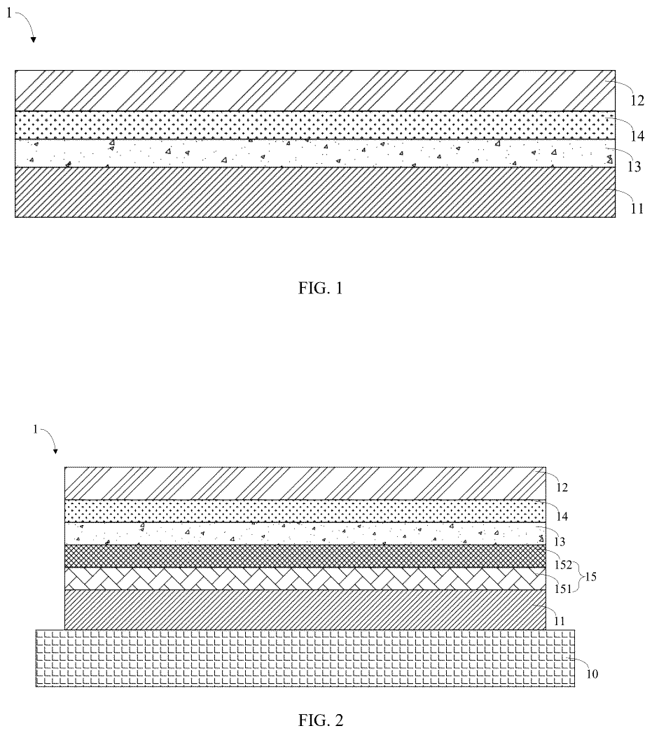

An embodiment of the present disclosure provides a photoelectric device, referring to FIG. 1, the photoelectric device includes an anode 11, a cathode 12 and multiple functional layers. A material of one of the multiple functional layers includes any one quantum dot of the present disclosure described above.

In some embodiments, each of the anode 11 and the cathode 12 independently is selected from one or more of a metal, a carbon material, and a second metal oxide. The metal includes but not limited to one or more of Al, Ag, Cu, Mo, Au, Ba, Pt, Ca, Ir, Ni, and Mg, the carbon material includes but not limited to one or more of graphite, carbon nanotube, graphene, and carbon fiber, and the second metal oxide includes but not limited to one or more of indium tin oxide (ITO), fluorine-doped tin oxide (FTO), antimony tin oxide (ATO), aluminium-doped zinc oxide (AZO), gallium-doped zinc oxide (GZO), indium-doped zinc oxide (IZO), magnesium-doped zinc oxide (IZO), SnO₂, ZnO, and In₂O₃. The anode 11 or the cathode 12 may be a composite electrode which has a sandwich-like structure. Each of a material of an upper layer and a material of a bottom layer each is a doped transparent metal oxide or a undoped transparent metal oxide, and a material of an intermediate layer is the metal. For example, the composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂. An average thickness of the intermediate layer does not exceed 35 nm. An average thickness of the anode 11 may range from 20 nm to 300 nm, and an average thickness of the cathode 12 may range from 20 nm to 300 nm.

In some embodiments, referring to FIG. 1, the multiple functional layers include an active layer 13, and a material of the active layer 13 includes any one quantum dot of the present disclosure described above. Optionally, the active layer 13 is a light-emitting layer or a light-absorbing layer.

The active layer 13 may include a plurality of quantum dot layers, a material of each quantum dot layer is independently selected from any one quantum dot of the present disclosure described above, and the quantum dot in each quantum dot layer may be arranged in a single layer. In order to improve a comprehensive performance of the photoelectric device and reduce a manufacturing cost of the photoelectric device, in some embodiments, an average thickness of the active layer 13 ranges from 10 nm to 100 nm, such as 10 nm, 20 nm, 30 nm, 40 nm, 50 nm, 60 nm, 70 nm, 80 nm, 90 nm, 100 nm, or a value between any two thereof.

In order to further improve the comprehensive performance of the photoelectric device 1, in some embodiments, referring to FIG. 1, the photoelectric device 1 further includes an electron functional layer 14 disposed between the cathode 12 and the active layer 13. An average thickness of the electron functional layer 14 may range from 10 nm to 200 nm. The electron functional layer 14 may have a single-layer structure or a multi-layers structure, for example, the electron functional layer 14 includes one or more of an electron injection layer, an electron transport layer, and a hole blocking layer. For the electron functional layer 14 including the electron injection layer, the electron transport layer, and the hole blocking layer, the electron injection layer, the electron transport layer, and the hole blocking layer may be disposed sequentially in stack, and the electron injection layer is closer to the cathode 12 than the hole blocking layer.

A material of the electron functional layer is selected from one or more of an undoped-type first inorganic compound and a doped-type second inorganic compound. The undoped-type first inorganic compound includes one or more of an undoped-type first metal oxide, a group IIB-VIA semiconductor material, a group IIIA-VA semiconductor material, and a group IB-IIIA-VIA semiconductor material. The undoped-type first metal oxide includes one or more of ZnO, TiO₂, SnO₂, BaO, Ta₂O₃, Al₂O₃, and ZrO₂. The group IIB-VIA semiconductor material includes one or more of ZnS, ZnSe, and CdS. The group IIIA-VA semiconductor material includes one or more of InP and GaP. The group IB-IIIA-VIA semiconductor material includes one or more of CuInS and CuGaS.

The doped-type second inorganic compound includes a doped-type second metal oxide, a host metal oxide of the doped-type second metal oxide is selected from ZnO, TiO₂, SnO₂, BaO, Ta₂O₃, Al₂O₃, or ZrO₂, and a doping element of the doped second metal oxide is selected from one or more of Mg, Ca, Zr, W, Ga, Li, Al, Ti, Y, In, and Sn.

In some embodiments, the doped-type second inorganic compound is selected from one or more of magnesium zinc oxide, calcium zinc oxide, zirconium zinc oxide, gallium zinc oxide, aluminum zinc oxide, lithium zinc oxide, titanium zinc oxide, yttrium zinc oxide, indium tin oxide, and lithium titanium oxide. For example, the doped-type second inorganic compound is selected from one or more of Zn₍₁₋ₓ₁₎Mgₓ₁O, Zn₍₁₋ₓ₁₎Caₓ₁O, Zn₍₁₋ₓ₁₎Zrₓ₁O, Zn₍₁₋ₓ₁₎Gaₓ₁O, Zn₍₁₋ₓ₁₎Alₓ₁O, Zn₍₁₋ₓ₁₎Liₓ₁O, Al₍₁₋ₓ₁₎Znₓ₁O, Zn₍₁₋ₓ₁₎Tiₓ₁O, Zn₍₁₋ₓ₁₎Yₓ₁O, In₍₁₋ₓ₁₎Snₓ₁O, and Ti₍₁₋ₓ₁₎Liₓ₁O, where x1 represents a molar amount, and 0<x≤0.5.

Under a condition that the electron functional layer 14 includes multiple materials and the electron functional layer 14 has the multi-layers structure, the multiple materials may all be in the same layer, or may be in different layers, or may be partially in the same layer.

In order to further improve the comprehensive performance and lifetime of the photoelectric device 1, in some embodiments, referring to FIG. 1, the photoelectric device 1 further includes a hole functional layer 15 disposed between the anode 11 and the active layer 13. The hole functional layer 15 may have a single-layer structure or a multi-layers structure, and for example, the hole functional layer 15 includes one or more of a hole injection layer, a hole transport layer, and an electron blocking layer. For the hole functional layer 15 including the hole injection layer, the hole transport layer, and the electron blocking layer, the hole injection layer, the hole transport layer, and the electron blocking layer may be disposed sequentially in stack, and the hole injection layer is closer to the anode 11 than the electron blocking layer. For example, an average thickness of the hole functional layer 15 ranges from 10 nm to 200 nm.

A material of the hole functional layer 15 includes but not limited to one or more of an undoped-type third inorganic compound, a doped-type fourth inorganic compound, and an organic compound. The organic compound includes but not limited to one or more of poly(3,4-ethylenedioxythiophene)-poly(styrenesulfonate) (PEDOT:PSS, CAS: 155090-83-8), copper(II) phthalocyanine (CAS: 147-14-8), titanyl phthalocyanine (CAS: 26201-32-1), 2,3,5,6-tetrafluoro-7,7,8,8-tetracyanoquinodimethane (CAS: 29261-33-4), hexaazatriphenylenehexacabonitrile (CAS: 105598-27-4), polyaniline (CAS: 25233-30-1), polypyrrole (CAS: 30604-81-0),poly(3-hexylthiophene-2,5-diyl)(CAS: 104934-50-1), poly(n-vinylcarbazole)(PVK, CAS: 25067-59-8), 4,4′-Bis(N-carbazolyl)-1,1′-biphenyl (CBP, CAS: 58328-31-7), poly[N,N′-bis(4-butylphenyl)-N,N′-bis(phenyl)-benzi (CAS: 472960-35-3), 4,4′-cyclohexylidenebis[N,N-bis(4-methylphenyl)aniline](TAPC, CAS: 58473-78-2), poly(9,9-dioctylfluorene-co-N-(4-butylphenyl)diphenylamine) (TFB, CAS: 220797-16-0), poly[(9,9-dioctylfluorenyl-2,7-diyl)-alt-(4,4′-(N-(4-butylphenyl) (CAS: 223569-31-1), 4,4′,4″-tris(N-3-methylphenyl-N-phenylamino)triphenylamine (CAS: 124729-98-2), 4,4′,4″-tris(carbazol-9-yl)-triphenylamine(TCTA, CAS: 139092-78-7), 4,4′,4″-tris[2-naphthyl(phenyl)amino]triphenylamine (CAS: 185690-41-9), N,N′-bis-(1-naphthalenyl)-N,N′-bis-phenyl-(1,1′-biphenyl)-4,4′-diamine (NPB, CAS: 123847-85-8), N,N′-bis(3-methylphenyl)-N,N′-diphenyl-benzidine (TPD, CAS: 65181-78-4), N,N′-bis[4-(diphenylamino)phenyl]-N,N′-diphenylbenzidine (CAS: 209980-53-0), N2,N7-diphenyl-N2,N7-di-m-tolyl-9,9′-spirobi[fluorene]-2,7-diamine (Spiro-TPD, CAS: 1033035-83-4), N2,N7-di-1-naphthalenyl-N2,N7-diphenyl-9,9′-spirobi[9h-fluorene]-2,7-diamine (CAS: 932739-76-9), poly[bis(4-phenyl)(2,4,6-trimethylphenyl)amine](PTTA, CAS: 1333317-99-9), and 2,2′,7,7′-Tetrakis[N,N-di(4-methoxyphenyl)amino]-9,9′-spirobifluorene (Spiro-omeTAD, CAS: 207739-72-8).

The undoped-type third inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, and tungsten sulphide. A host inorganic compound of the doped-type fourth inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, and tungsten sulphide, and a doping element of the doped-type fourth inorganic compound is selected from one or more of nickel, molybdenum, tungsten, vanadium, chromium, copper and platinum group metal elements, and a mole percentage of the doping element is not more than 50%.

Under a condition that the hole functional layer 15 includes multiple materials and the hole functional layer 15 has the multi-layers structure, the multiple materials may all be in the same layer, or may be in different layers, or may be partially in the same layer. For example, referring to FIG. 2, the hole functional layer 15 is formed of a hole injection layer and a hole transport layer disposed in stack. The material of the hole functional layer 15 includes poly(3,4-ethylenedioxythiophene)-poly(styrenesulfonate) (PEDOT:PSS) and poly(9,9-dioctylfluorene-co-N-(4-butylphenyl)diphenylamine) (TFB), PEDOT:PSS and poly(9,9-dioctylfluorene-co-N-(4-butylphenyl)diphenylamine) are in different layers, a material of the hole injection layer is PEDOT:PSS, and a material of the hole transport layer is TFB.

A method for preparing each functional layer in the photoelectric device includes but not limited to a chemical method and/or a physical method. The chemical method includes but not limited to one or more of a chemical vapor deposition method, a continuous ion layer adsorption and reaction method, an anodic oxidation method, an electrolytic deposition method, and a co-precipitation method. The physical method includes but not limited to a physical coating method and a solution method. The physical coating method includes but not limited to one or more of a thermal evaporation coating method, an electron beam evaporation coating method, a magnetron sputtering method, a multi-arc ion coating method, a physical vapor deposition method, an atomic layer deposition method, and a pulsed laser deposition method. The solution method includes but not limited to one or more of a spin coating method, a printing method, an ink jet printing method, a blade coating method, a dip coating method, a roll coating method, a casting method, a slit coating method, and a strip coating method. When a functional film layer is prepared by the solution method, a drying step may be added to remove a solvent to form a cured film. The drying step includes but not limited to a heat treatment, a vacuum drying treatment, or a natural air drying treatment. For preparing a functional film layer including an inorganic compound over the active layer, especially the inorganic compound is an inorganic nanoparticle, after the cured film is formed by a low-temperature (not higher than 80° C.) drying process such as the vacuum drying treatment or the natural air drying treatment, in order to further improve a film formation quality, the cured film may be further annealed by a process capable of controlling the annealing depth, such as a laser annealing, an electron beam annealing, an atomic annealing, or an infrared irradiation annealing.

After all functional layers of the photoelectric device having been prepared, an encapsulating step is performed. The encapsulating step may be a commonly used machine encapsulating or a manually encapsulating. In the encapsulating environment, a content of oxygen and a content of water are both lower than 0.1 ppm to ensure a stability of the photoelectric device.

An embodiment of the present disclosure provides an electronic device including any one photoelectric device of the present disclosure described above. The electronic device may be any electronic product with a display function, including but not limited to a smartphone, a tablet computer, a notebook computer, a digital camera, a digital video camera, a smart wearable device, a smart weighing electronic scale, a vehicle display, a television or an electronic book. The smart wearable device may be, for example, a smart bracelet, a smart watch, a virtual reality helmet, or the like.

In the following, the present disclosure is specifically described by specific embodiments, and the following examples are only partial examples of the present disclosure, and the present disclosure is not limited thereto.

In a method for preparing the basic solution, 10 mmol of zinc acetate, 0.3 mmol of cadmium oxide, 20 mL of oleic acid and 80 mL of 1-octadecene were sequentially added into a 250 mL three-neck flask, and an argon gas was introduced at room temperature with a flow rate of 100 mL/min. After expelling air for 15 minutes, the basic solution was obtained after heating at 150° C. under an argon atmosphere for 60 minutes.

In a method for preparing a S-TOP solution, 5 mmol of sulfur powder and 10 mL TOP were sequentially added into a 50 mL three-neck flask, and an argon gas was introduced at room temperature with a flow rate of 50 mL/min. After expelling air for 15 minutes, the S-TOP solution was obtained after heating at 150° C. while stirring under an argon atmosphere until the sulfur powder was completely dispersed.

In a method for preparing a Se-TOP solution, 5 mmol of selenium powder and 10 mL TOP were sequentially added into a 50 mL three-neck flask, and an argon gas was introduced at room temperature with a flow rate of 50 mL/min. After expelling air for 15 minutes, the Se-TOP solution was obtained after heating at 150° C. while stirring under an argon atmosphere until the selenium powder was completely dispersed.

In a method for purifying the quantum dot includes the steps S21˜S24.

In a method for preparing a cadmium oleate solution, 5 mmol of cadmium oxide, 5 mL of oleic acid and 20 mL of 1-octadecene were sequentially added into a 100 ml three-neck flask sequentially, and an argon gas was introduced at room temperature with a flow rate of 100 mL/min. After expelling air for 15 minutes, the cadmium oleate solution with a concentration of 0.2 mmol/mL was obtained by heating at 150° C. for 60 minutes and then heating at 240° C. for 30 minutes.

### Example 1

The present embodiment provides a photoelectric device and a preparation method thereof. The photoelectric device is a quantum dot light emitting diode with an upright structure. Referring to FIG. 2, the photoelectric device includes a substrate 10, an anode 11, a hole functional layer 15, an active layer 13, an electron functional layer 14, and a cathode 12 disposed sequentially in stack. The hole functional layer 15 is formed of a hole injection layer 151 and a hole transport layer 152 disposed in stack, and the hole injection layer 151 is closer to the anode 11 than the hole transport layer 152. The electron functional layer 14 has a monolayer structure.

A material of the substrate 10 includes glass, and an average thickness of the substrate 10 is 2 mm. A material of the anode 11 includes ITO, and an average thickness of the anode 11 is 110 nm. A material of the cathode 12 includes silver, and an average thickness of the cathode 12 is 100 nm. A material of the electron functional layer 14 includes zinc oxide nanoparticles, an average particle size of the zinc oxide nanoparticles is 4 nm, and an average thickness of the electron functional layer 14 is 40 nm. A material of the hole injection layer 151 includes PEDOT:PSS, and an average thickness of the hole injection layer 151 is 60 nm. A material of the hole transport layer 152 includes TFB, and an average thickness of the hole transport layer 152 is 70 nm.

A material of the active layer 13 includes a quantum dot of Zn_{0.9}Cd_{0.1}Se/ZnSe/Zn_{0.78}Cd_{0.22}S/Zn_{0.5}Cd_{0.5}S/ZnS. A material of a core of the quantum dot is Zn_{0.9}Cd_{0.1}Se, and a particle size of the core is 4 nm. A material of an auxiliary shell layer of the quantum dot is ZnSe, and an average thickness of the auxiliary shell layer is 0.9 nm. A material of a first shell layer is Zn_{0.78}Cd_{0.22}S, and an average thickness of the first shell layer is 0.9 nm. A material of a second shell layer was Zn_{0.5}Cd_{0.5}S, and an average thickness of the second shell layer is 0.4 nm. A material of a third shell layer is ZnS, and an average thickness of the third shell layer is 1.5 nm.

A method for preparing the photoelectric device includes steps S1.1˜S1.6.

In step S1.1, ITO was sputtered on one side of the substrate to obtain an ITO layer. A surface of the ITO layer was wiped with a cotton swab dipped in a small amount of soapy water to remove visible impurities on the surface. The substrate including the ITO layer was ultrasonically cleaned by deionized water for 15 minutes, acetone for 15 minutes, ethanol for 15 minutes and isopropyl alcohol for 15 minutes sequentially, and after drying, the substrate including the anode was obtained by an ultraviolet-ozone surface treatment for 20 minutes.

In step S1.2, a PEDOT:PSS aqueous solution with a concentration of 10 mg/mL was spin-coated on one side of the anode away from the substrate under an air atmosphere with a normal temperature and a normal pressure, and then the hole injection layer was formed by heating at 115° C. for curing.

In step S1.3, a TFB solution with a concentration of 8 mg/mL was spin-coated on the side of the hole injection layer away from the anode under a nitrogen atmosphere with a normal temperature and a normal pressure, and then the hole transport layer was formed by heating at 125° C. for curing. A solvent of the TFB solution was chlorobenzene.

In step S1.4, a quantum dot solution with a concentration of 30 mg/mL was spin-coated on one side of the hole transport layer away from the hole injection layer under a nitrogen atmosphere with a normal temperature and a normal pressure, and then the active layer was formed by heating at 110° C. for curing. A solvent of the quantum dot solution was n-octane.

In step S1.5, a zinc oxide nanoparticles solution with a concentration of 30 mg/mL was spin-coated on one side of the active layer away from the hole transport layer under a nitrogen atmosphere with a normal temperature and a normal pressure, and then the electron functional layer was formed by heating at 100° C. for curing. A solvent of the zinc oxide nanoparticles solution was ethyl alcohol.

In step S1.6, a prefabricated device obtained after the step S1.5 was transferred to an evaporation machine, and then the cathode was formed on one side of the electron functional layer away from the active layer by depositing silver atomic vapour, finally, an encapsulating step was performed to obtain the photoelectric device. The silver atomic vapour was generated by using an electron beam with a current of 35 A to bombard silver.

A method for preparing the quantum dot of Zn_{0.9}Cd_{0.1}Se/ZnSe/Zn_{0.78}Cd_{0.22}S/Zn_{0.5}Cd_{0.5}S/ZnS includes steps S10.1˜S10.5.

In step S10.1, the basic solution was heated to 300° C., then 6 mL of the Se-TOP solution was rapidly injected into the basic solution, and a first solution including the core was obtained by ripening for 20 minutes.

In step S10.2, 4 mL of the Se-TOP solution was injected into the first solution at 300° C. with a rate of 8 mL/h, and a second solution including the core and the auxiliary shell layer was obtained after a mixing reaction for 5 minutes. In the second solution, the core was wrapped by the auxiliary shell layer.

In step S10.3, 4 mL of the S-TOP solution was injected into the second solution at 300° C. with a rate of 8 mL/h, while 2.2 mL of the cadmium oleate solution was injected into the second solution at 300° C. with a rate of 4.4 mL/h, and a third solution including the core, the auxiliary shell layer, and the first shell layer was obtained after a ripening reaction at 300° C. for 40 minutes. In the third solution, the auxiliary shell layer was wrapped by the first shell layer.

In step S10.4, 2 mL of the S-TOP solution was injected into the third solution at 300° C. with a rate of 8 mL/h, while 2.5 mL of the cadmium oleate solution was injected into the third solution at 300° C. with a rate of 10 mL/h, and a fourth solution including the core, the auxiliary shell layer, the first shell layer, and the second shell layer was obtained after a mixing reaction. In the fourth solution, the first shell layer was wrapped by the second shell layer.

In step S10.5, 8 mL of the S-TOP solution was injected into the third solution at 300° C. with a rate of 8 mL/h, a reaction solution including the quantum dot after a mixing reaction. After the reaction solution was cooled to room temperature, the reaction solution was purified to obtain a purified quantum dot.

### Example 2

The present embodiment provides a photoelectric device and a preparation method thereof. Compared with the photoelectric device in Example 1, the photoelectric device of the present embodiment has a difference that the average thickness of the auxiliary shell layer is 1.2 nm.

A method for preparing the photoelectric device was carried out with reference to the Example 1.

Compared with the method for preparing the quantum dot in Example 1, a method for preparing the quantum dot of the present embodiment has a difference in step S10.2. In the present embodiment, in step S10.2, 6 mL of the Se-TOP solution was injected into the first solution at 300° C. with a rate of 8 mL/h, and a second solution including the core and the auxiliary shell layer was obtained after a mixing reaction for 5 minutes. In the second solution, the core was wrapped by the auxiliary shell layer.

### Example 3

The present embodiment provides a photoelectric device and a preparation method thereof. Compared with the photoelectric device in Example 1, the photoelectric device of the present embodiment has a difference that the material of the active layer includes a quantum dot of Zn_{0.9}Cd_{0.1}Se/ZnSe/ZnS/Zn_{0.5}Cd_{0.5}S/ZnS. In the quantum dot of Zn_{0.9}Cd_{0.1}Se/ZnSe/ZnS/Zn_{0.5}Cd_{0.5}S/ZnS, a particle size of the core is 4 nm, an average thickness of the auxiliary shell layer is 1.2 nm, an average thickness of the first shell layer is 0.9 nm, an average thickness of the second shell layer is 0.4 nm, and an average thickness of the third shell layer is 1.5 nm.

A method for preparing the photoelectric device was carried out with reference to the Example 1.

A method for preparing the quantum dot of Zn_{0.9}Cd_{0.1}Se/ZnSe/ZnS/Zn_{0.5}Cd_{0.5}S/ZnS includes steps S11.1˜S11.5.

Step S11.1 was the same as Step S10.1.

In step S11.2, 6 mL of the Se-TOP solution was injected into the first solution at 300° C. with a rate of 8 mL/h, and a second solution including the core and the auxiliary shell layer was obtained after a mixing reaction for 5 minutes. In the second solution, the core was wrapped by the auxiliary shell layer.

In step S11.3, 4 mL of the S-TOP solution was injected into the second solution at 300° C. with a rate of 8 mL/h, and a third solution including the core, the auxiliary shell layer, and the first shell layer was obtained after a ripening reaction at 300° C. for 40 minutes. In the third solution, the auxiliary shell layer was wrapped by the first shell layer.

Step S11.4 was the same as the Step S10.4, and Step S11.5 was the same as the Step S10.5.

### Example 4

The present embodiment provides a photoelectric device and a preparation method thereof. Compared with the photoelectric device in Example 1, the photoelectric device of the present embodiment has a difference that the average thickness of the auxiliary shell layer is 0.9 nm.

A method for preparing the photoelectric device was carried out with reference to the Example 1.

Compared with the method for preparing the quantum dot in Example 1, a method for preparing the quantum dot of the present embodiment has a difference in step S10.2. In the present embodiment, in step S10.2, 4 mL of the Se-TOP solution was injected into the first solution at 300° C. with a rate of 8 mL/h, and a second solution including the core and the auxiliary shell layer was obtained after a mixing reaction for 5 minutes. In the second solution, the core was wrapped by the auxiliary shell layer.

### Example 5

The present embodiment provides a photoelectric device and a preparation method thereof. Compared with the photoelectric device in Example 1, the photoelectric device of the present embodiment has a difference that the material of the active layer includes a quantum dot of Zn_{0.9}Cd_{0.1}Se/Zn_{0.68}Cd_{0.32}Se/ZnS/Zn_{0.5}Cd_{0.5}S/ZnS. In the quantum dot of Zn_{0.9}Cd_{0.1}Se/Zn_{0.68}Cd_{0.32}Se/ZnS/Zn_{0.5}Cd_{0.5}S/ZnS, a particle size of the core is 4 nm, an average thickness of the auxiliary shell layer is 0.9 nm, an average thickness of the first shell layer is 0.9 nm, an average thickness of the second shell layer is 0.4 nm, and an average thickness of the third shell layer is 1.5 nm.

A method for preparing the photoelectric device was carried out with reference to the Example 1.

A method for preparing the quantum dot of Zn_{0.9}Cd_{0.1}Se/Zn_{0.68}Cd_{0.32}Se/ZnS/Zn_{0.5}Cd_{0.5}S/ZnS includes steps S12.1˜S12.5.

Step S12.1 was the same as the Step S10.1.

In step S12.2, 4 mL of the Se-TOP solution was injected into the first solution at 300° C. with a rate of 8 mL/h, while 3.2 mL of the cadmium oleate solution was injected into the first solution at 300° C. with a rate of 6.4 mL/h, and a second solution including the core and the auxiliary shell layer was obtained after a mixing reaction for 5 minutes. In the second solution, the core was wrapped by the auxiliary shell layer.

In step S12.3, 4 mL of the S-TOP solution was injected into the second solution at 300° C. with a rate of 8 mL/h, and a third solution including the core, the auxiliary shell layer, and the first shell layer was obtained after a ripening reaction at 300° C. for 40 minutes. In the third solution, the auxiliary shell layer was wrapped by the first shell layer.

Step S12.4 was the same as the Step S10.4, and Step S12.5 was the same as the Step S10.5.

### Example 6

The present embodiment provides a photoelectric device and a preparation method thereof. Compared with the photoelectric device in Example 1, the photoelectric device of the present embodiment has a difference that the material of the active layer includes a quantum dot of Zn_{0.9}Cd_{0.1}Se/Zn_{0.68}Cd_{0.32}Se/Zn_{0.65}Cd_{0.35}S/Zn_{0.5}Cd_{0.5}S/ZnS. In the quantum dot of Zn_{0.9}Cd_{0.1}Se/Zn_{0.68}Cd_{0.32}Se/Zn_{0.65}Cd_{0.35}S/Zn_{0.5}Cd_{0.5}S/ZnS, a particle size of the core is 4 nm, an average thickness of the auxiliary shell layer is 0.9 nm, an average thickness of the first shell layer is 0.9 nm, an average thickness of the second shell layer is 0.4 nm, and an average thickness of the third shell layer is 1.5 nm.

A method for preparing the photoelectric device was carried out with reference to the Example 1.

A method for preparing the quantum dot of Zn_{0.9}Cd_{0.1}Se/Zn_{0.68}Cd_{0.32}Se/Zn_{0.65}Cd_{0.35}S/Zn_{0.5}Cd_{0.5}S/ZnS includes steps S13.1˜S13.5.

Step S13.1 was the same as the Step S10.1.

In step S13.2, 4 mL of the Se-TOP solution was injected into the first solution at 300° C. with a rate of 8 mL/h, while 3.2 mL of the cadmium oleate solution was injected into the first solution at 300° C. with a rate of 6.4 mL/h, and a second solution including the core and the auxiliary shell layer was obtained after a mixing reaction for 5 minutes. In the second solution, the core was wrapped by the auxiliary shell layer.

In step S13.3, 4 mL of the S-TOP solution was injected into the second solution at 300° C. with a rate of 8 mL/h, while 3.5 mL of the cadmium oleate solution was injected into the second solution at 300° C. with a rate of 7 mL/h, and a third solution including the core, the auxiliary shell layer, and the first shell layer was obtained after a ripening reaction at 300° C. for 40 minutes. In the third solution, the auxiliary shell layer was wrapped by the first shell layer.

Step S13.4 was the same as the Step S10.4, and Step S13.5 was the same as the Step S10.5.

### Example 7

The present embodiment provides a photoelectric device and a preparation method thereof. Compared with the photoelectric device in Example 1, the photoelectric device of the present embodiment has a difference that the material of the active layer includes a quantum dot of Zn_{0.9}Cd_{0.1}Se/Zn_{0.65}Cd_{0.35}S/Zn_{0.5}Cd_{0.5}S/ZnS. In the quantum dot of Zn_{0.9}Cd_{0.1}Se/Zn_{0.65}Cd_{0.35}S/Zn_{0.5}Cd_{0.5}S/ZnS, a particle size of the core is 4 nm, an average thickness of the first shell layer is 1.2 nm, an average thickness of the second shell layer is 0.4 nm, and an average thickness of the third shell layer is 1.5 nm.

A method for preparing the photoelectric device was carried out with reference to the Example 1.

A method for preparing the quantum dot of Zn_{0.9}Cd_{0.1}Se/Zn_{0.65}Cd_{0.35}S/Zn_{0.5}Cd_{0.5}S/ZnS includes steps S14.1˜S14.5.

Step S14.1 was the same as the Step S10.1.

In step S14.2, 6 mL of the S-TOP solution was injected into the first solution at 300° C. with a rate of 8 mL/h, while 5.25 mL of the cadmium oleate solution was injected into the first solution at 300° C. with a rate of 7 mL/h, a second solution including the core and the first shell layer was obtained after a mixing reaction for 5 minutes. In the second solution, the core was wrapped by the first shell layer.

In step S14.3, 2 mL of the S-TOP solution was injected into the second solution at 300° C. with a rate of 8 mL/h, while 2.5 mL of the cadmium oleate solution was injected into the second solution at 300° C. with a rate of 10 mL/h, and a third solution including the core, the auxiliary shell layer, and the first shell layer was obtained after a ripening reaction at 300° C. for 40 minutes. In the third solution, the auxiliary shell layer was wrapped by the first shell layer.

In step S14.4, 8 mL of the S-TOP solution was injected into the third solution at 300° C. with a rate of 8 mL/h, a reaction solution including the quantum dot after a mixing reaction. After the reaction solution was cooled to room temperature, the reaction solution was purified to obtain a purified quantum dot.

### Example 8

The present embodiment provides a photoelectric device and a preparation method thereof. Compared with the photoelectric device in Example 1, the photoelectric device of the present embodiment has differences that the average thickness of the auxiliary shell layer is 1.2 nm and the average thickness of the first shell layer is 1.2 nm.

A method for preparing the photoelectric device was carried out with reference to the Example 1.

Compared with the method for preparing the quantum dot in Example 1, a method for preparing the quantum dot of the present embodiment has differences in step S10.2 and S10.3.

In the present embodiment, in step S10.2, 6 mL of the Se-TOP solution was injected into the first solution at 300° C. with a rate of 8 mL/h, and a second solution including the core and the auxiliary shell layer was obtained after a mixing reaction for 5 minutes. In the present embodiment, in step S10.3, 6 mL of the S-TOP solution was injected into the second solution at 300° C. with a rate of 8 mL/h, while 2.2 mL of the cadmium oleate solution was injected into the second solution at 300° C. with a rate of 4.4 mL/h, and a third solution including the core, the auxiliary shell layer, and the first shell layer was obtained after a ripening reaction at 300° C. for 40 minutes.

### Comparative Example 1

The present comparative example provides a photoelectric device and a preparation method thereof. Compared with the photoelectric device in Example 1, the photoelectric device of the present comparative example has a difference that the material of the active layer includes a quantum dot of Zn_{0.9}Cd_{0.1}Se/ZnSe/Zn_{0.5}Cd_{0.5}S/ZnS. In the quantum dot of Zn_{0.9}Cd_{0.1}Se/ZnSe/Zn_{0.5}Cd_{0.5}S/ZnS, a particle size of the core of Zn_{0.9}Cd_{0.1}Se was 4 nm, an average thickness of the first shell layer is 0.9 nm, an average thickness of the second shell layer is 0.4 nm, and an average thickness of the third shell layer is 1.5 nm.

A method for preparing the photoelectric device was carried out with reference to the Example 1.

A method for preparing the quantum dot of Zn_{0.9}Cd_{0.1}Se/ZnSe/Zn_{0.5}Cd_{0.5}S/ZnS includes steps S15.1˜S15.4.

Step S15.1 was the same as the Step S10.1.

In step S15.2, 4 mL of the Se-TOP solution was injected into the first solution at 300° C. with a rate of 8 mL/h, a second solution including the core and the first shell layer was obtained after a mixing reaction for 5 minutes. In the second solution, the core was wrapped by the first shell layer.

In step S15.3, 2 mL of the S-TOP solution was injected into the second solution at 300° C. with a rate of 8 mL/h, while 2.5 mL of the cadmium oleate solution was injected into the second solution at 300° C. with a rate of 10 mL/h, and a third solution including the core, the first shell layer, and the second shell layer was obtained after a mixing reaction. In the third solution, the first shell layer was wrapped by the second shell layer.

In step S15.4, 8 mL of the S-TOP solution was injected into the third solution at 300° C. with a rate of 8 mL/h, a reaction solution including the quantum dot after a mixing reaction. After the reaction solution was cooled to room temperature, the reaction solution was purified to obtain a purified quantum dot.

### Comparative Example 2

The present comparative example provides a photoelectric device and a preparation method thereof. Compared with the photoelectric device in Example 1, the photoelectric device of the present comparative example has a difference that the material of the active layer includes a quantum dot of Zn_{0.9}Cd_{0.1}Se/ZnS/Zn_{0.5}Cd_{0.5}S/ZnS. In the quantum dot of Zn_{0.9}Cd_{0.1}Se/ZnS/Zn_{0.5}Cd_{0.5}S/ZnS, a particle size of the core of Zn_{0.9}Cd_{0.1}Se is 4 nm, an average thickness of the first shell layer is 0.9 nm, an average thickness of the second shell layer is 0.4 nm, and an average thickness of the third shell layer is 1.5 nm.

A method for preparing the photoelectric device was carried out with reference to the Example 1.

A method for preparing the quantum dot of Zn_{0.9}Cd_{0.1}Se/ZnS/Zn_{0.5}Cd_{0.5}S/ZnS includes steps S16.1˜S16.4.

Step S16.1 was the same as the Step S10.1.

In step S16.2, 4 mL of the S-TOP solution was injected into the first solution at 300° C. with a rate of 8 mL/h, a second solution including the core and the first shell layer was obtained after a mixing reaction for 5 minutes. In the second solution, the core was wrapped by the first shell layer.

In step S15.3, 2 mL of the S-TOP solution was injected into the second solution at 300° C. with a rate of 8 mL/h, while 2.5 mL of the cadmium oleate solution was injected into the second solution at 300° C. with a rate of 10 mL/h, and a third solution including the core, the first shell layer, and the second shell layer was obtained after a mixing reaction. In the third solution, the first shell layer was wrapped by the second shell layer.

In step S15.4, 8 mL of the S-TOP solution was injected into the third solution at 300° C. with a rate of 8 mL/h, a reaction solution including the quantum dot after a mixing reaction. After the reaction solution was cooled to room temperature, the reaction solution was purified to obtain a purified quantum dot.

### Test Example 1

A Photoluminescence wavelength, a full width at half maximum, and a photoluminescence efficiency of the quantum dot in the active layer of the photoelectric device in each of Examples 1 to 8, Comparative Example 1, and Comparative Example 2 are shown in Table 1 below:

TABLE 1

| | photo- | full width | photo- |
|---|---|---|---|
| | luminescence | at half | luminescence |
| | wavelength | maximum | efficiency |
| items | (nm) | (nm) | (%) |
| Example 1 | 475 | 22 | 39.2 |
| Example 2 | 474 | 22 | 40.5 |
| Example 3 | 473 | 20.6 | 40.9 |
| Example 4 | 475 | 23 | 42.3 |
| Example 5 | 477 | 21.4 | 35.6 |
| Example 6 | 478 | 22.4 | 38.9 |
| Example 7 | 475 | 21 | 40.6 |
| Example 8 | 470 | 19.2 | 52.8 |
| Comparative | 482 | 25 | 25.3 |
| Example 1 | | | |
| Comparative | 480 | 23.8 | 30.6 |
| Example 2 | | | |

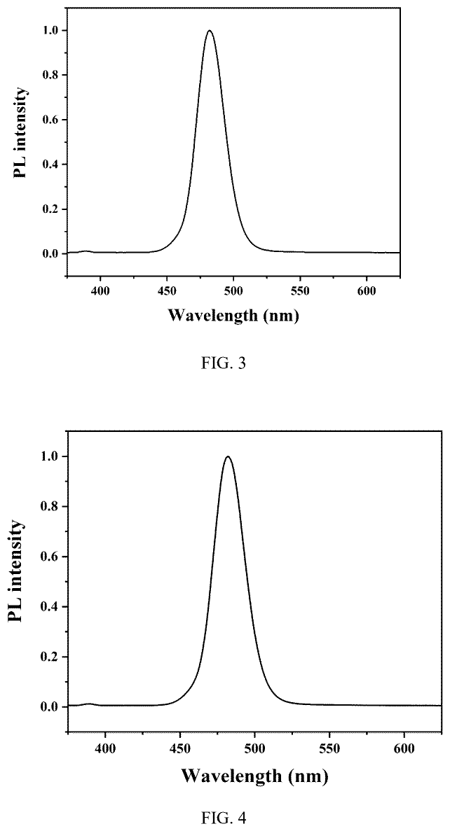

The photoluminescence wavelength, the full width at half maximum and the photoluminescence efficiency were all detected by a quantum dot-n-hexane solution with a concentration of 0.5 mg/mL. FIG. 3 and FIG. 4 show photoluminescence spectroscopies of the quantum dots in Example 1, Comparative Example 1 and Comparative Example 2, respectively. Referring to FIG. 3 and FIG. 4, compared with the quantum dot in Comparative Example 1 or Comparative Example 2, a photoluminescence peak of the quantum dot in Example 1 has a certain degree blue shift.

### Test Example 2

Performances of photoelectric devices in Examples 1 to 8, Comparative Example 1, and Comparative Example 2 were tested. A turn-on voltage, a current, a maximum brightness, a luminescence spectrum and other parameters of each photoelectric device were detected by a Fostar FPD optical characteristic measuring equipment, and lifetime of each photoelectric device was tested by a life testing equipment. Tests were performed in an environment with a temperature of 25° C. and a humidity of 50%.

External quantum efficiency (EQE) was tested by an EQE optical testing instrument, and a maximum external quantum efficiency (EQEₘₐₓ,%) was calculated.

Driven by a constant current (2 mA), the life testing equipment was configured to analyse the lifetime of each photoelectric device. A time required for each photoelectric device to decay from the maximum brightness to 95% thereof was recorded. A time required for each photoelectric device to decay from 100% to 95% at 1000 nit brightness was calculated by attenuation fitting formula, and the time was defined as T95@1000 nit.

The EQEₘₐₓ, the turn-on voltage and the T95@1000 nit of each photoelectric device in a first state and a second state were respectively detected. The first state was that the encapsulating step was just completed, and the second state was that the photoelectric device was continuously energized for 48 hours after the encapsulating step.

Moreover, an electroluminescence peak of each photoelectric device in the first state and a third state were respectively detected. The third state was that the photoelectric device was continuously energized for 24 hours after the encapsulating step.

Test results of photoelectric devices in the first state are shown in Table 2 below:

TABLE 2

| | EQEₘₐₓ | turn-on voltage | T95@1000 nit |
|---|---|---|---|
| items | (%) | (V) | (h) |
| Example 1 | 18.2 | 2.13 | 54.9 |
| Example 2 | 18.8 | 2.04 | 60.8 |
| Example 3 | 20.6 | 1.95 | 70.5 |
| Example 4 | 16.2 | 4.04 | 31.8 |
| Example 5 | 20.9 | 1.98 | 75.6 |
| Example 6 | 19.8 | 1.84 | 74.8 |
| Example 7 | 20.6 | 1.84 | 78.2 |
| Example 8 | 19.1 | 1.96 | 67.8 |
| Comparative | 17.3 | 4.12 | 35.2 |
| Example 1 | | | |
| Comparative | 17.2 | 4.38 | 37.6 |
| Example 2 | | | |

Test results of photoelectric devices in the second state are shown in Table 3 below:

TABLE 3

| | EQEₘₐₓ | turn-on voltage | T95@1000 nit |
|---|---|---|---|
| items | (%) | (V) | (h) |
| Example 1 | 14.5 | 4.54 | 25.6 |
| Example 2 | 15.2 | 4.08 | 30.2 |
| Example 3 | 14.6 | 5.03 | 29.7 |
| Example 4 | 9.2 | 7.25 | 12.8 |
| Example 5 | 15.6 | 4.98 | 31.6 |
| Example 6 | 14.5 | 4.76 | 34.2 |
| Example 7 | 15.4 | 4.92 | 34.5 |
| Example 8 | 15.6 | 4.02 | 32.0 |
| Comparative | 9.4 | 7.02 | 11.9 |
| Example 1 | | | |
| Comparative | 8.9 | 8.09 | 10.6 |
| Example 2 | | | |

As can be seen from Tables 1 and 2, performance stability of photoelectric devices in Examples 1 to 8 are more advantageous than photoelectric devices in Comparative Example 1 and Comparative Example 2. Taking the photoelectric device in Example 2 as an example, the EQEₘₐₓ in the second state only decreases by 3.6% compared with that in the first state, the turn-on voltage in the second state only increases by 2.04 V compared with that in the first state, and the T95@1000 nit in the second state decreases by 50% than that in the first state. For the photoelectric device in Comparative Example 2, the EQEₘₐₓ in the second state decreases by 8.3% compared with that in the first state, the turn-on voltage in the second state increases by 2.64 V compared with that in the first state, and the T95@1000 nit in the second state decreases by 72% compared with that in the first state. Furthermore, both in the first state and in the second state, photoelectric properties and lifetime of photoelectric devices in Examples 1 to 8 are better.

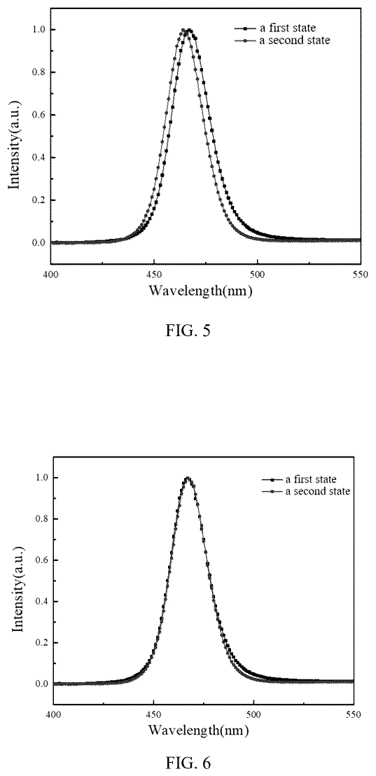

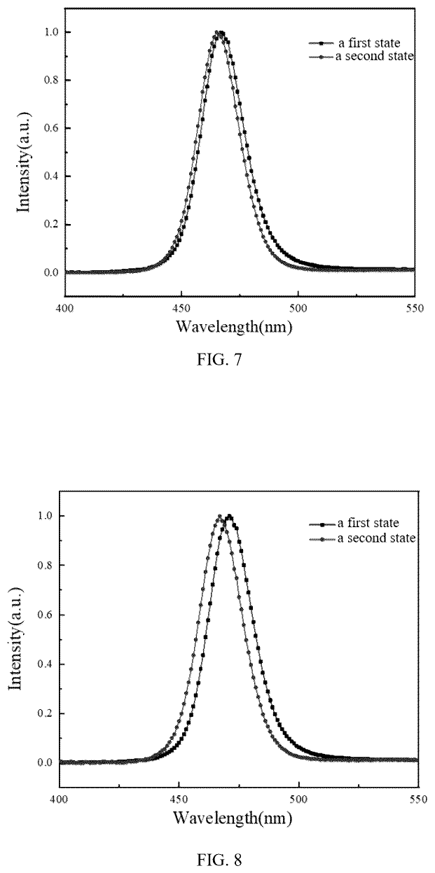

Referring to FIG. 5 to FIG. 8, during a working process of the photoelectric device, with an extension of the powered time, the electroluminescence peak of the photoelectric device in Comparative Example 2 shows an obvious “blue shift” phenomenon, so the performance stability of the photoelectric device in Comparative Example 2 is poor. A reason may be that the cadmium ions in the core and/or the cadmium ions in the second shell layer may migrate to other shell layers, resulting in widening the band gap of the quantum dot, weakening the trap characteristics of the shell layers, and weakening the long-wavelength luminescence. Compared with the photoelectric device in the Comparative Example 2, the “blue shift” phenomenon of the photoelectric device in the Examples 1 to 3 is obviously weakened, in particular to the photoelectric device in the Example 2, the blue shift hardly occurs within continuously energizing for 24 hours after the encapsulating step.

Therefore, using the quantum dot of the present disclosure as the material of the active layer in the photoelectric device might effectively improve a problem of the blue shift, thereby improving the performance stability of the photoelectric device.

The quantum dot and the preparation method thereof, and the photoelectric device provided by embodiments of the present disclosure are described in detail above, and specific examples have been applied herein to illustrate principles and implement measures. The foregoing description of embodiments is provided merely to help understand a method and a core idea of the present disclosure. Those skilled in the art may change specific embodiments and scope of the present disclosure according to ideas of the present disclosure. In summary, contents of the specification should not be construed as limiting the present disclosure.

What is claimed is:

1. A quantum dot with a core-shell structure, wherein in a direction of a core of the quantum dot towards an outermost shell layer of the quantum dot, mole percentages of cadmium in the core and shell layers comprising cadmium gradually increase.

2. The quantum dot according to claim 1, wherein the shell layers of the quantum dot comprise a first shell layer, a second shell layer and a third shell layer arranged sequentially, the first shell layer is closer to the core of the quantum dot than the third shell layer, the core of the quantum dot comprises cadmium, and at least one of the first shell layer, the second shell layer, and the third shell layer comprises cadmium.

3. The quantum dot according to claim 2, wherein a material of the core of the quantum dot is ZnₓCd₍₁₋ₓ₎A, a material of the first shell layer is ZnD or ZnₜCd₍₁₋ₜ₎D, a material of the second shell layer is Zn_{y}Cd_{(1-y)}E, and a material of the third shell layer is ZnG or ZnₘCd₍₁₋ₘ₎G; each of A, D and G is independently selected from Se or S, and x>t>y>m.

4. The quantum dot according to claim 3, wherein a structural composition of the quantum dot is ZnₓCd₍₁₋ₓ₎A/ZnₜCd₍₁₋ₜ₎D/Zn_{y}Cd_{(1-y)}E/ZnG, where x ranges from 0.8 to 0.95, t ranges from 0.62 to 0.8, and y ranges from 0.4 to 0.6.

5. The quantum dot according to claim 4, wherein t ranges from 0.65 to 0.76.

6. The quantum dot according to claim 2, wherein the shell layers of the quantum dot further comprise an auxiliary shell layer disposed between the core of the quantum dot and the first shell layer; the auxiliary shell layer does not comprise cadmium, or the auxiliary shell layer comprises cadmium, and the mole percentage of cadmium in the auxiliary shell layer is higher than the mole percentage of cadmium in the core of the quantum dot.

7. The quantum dot according to claim 6, wherein a material of the auxiliary shell layer is selected from ZnR or Zn_{z}Cd_{(1-z)}R, where R is selected from Se or S, and z ranges from 0.62 to 0.8;
an average thickness of the auxiliary shell layer ranges from 0.8 nm to 1.5 nm.

8. The quantum dot according to claim 1, wherein the structural composition of the quantum dot is ZnₓCd₍₁₋ₓ₎A/ZnR/ZnD/Zn_{y}Cd_{(1-y)}E/ZnG, where x ranges from 0.8 to 0.95 and y ranges from 0.4 to 0.6; or the structural composition of the quantum dot is ZnₓCd₍₁₋ₓ₎A/ZnR/ZnₜCd₍₁₋ₜ₎D/Zn_{y}Cd_{(1-y)}E/ZnG, where x ranges from 0.8 to 0.95, t ranges from 0.62 to 0.8, and y ranges from 0.4 to 0.6; or the structural composition of the quantum dot is ZnₓCd₍₁₋ₓ₎A/Zn_{z}Cd_{(1-z)}R/ZnD/Zn_{y}Cd_{(1-y)}E/ZnG, where x ranges from 0.8 to 0.95, z ranges from 0.62 to 0.8, and y ranges from 0.4 to 0.6; or the structural composition of the quantum dot is ZnₓCd₍₁₋ₓ₎A/Zn_{z}Cd_{(1-z)}R/ZnₜCd₍₁₋ₜ₎D/Zn_{y}Cd_{(1-y)}E/ZnG, where x ranges from 0.8 to 0.95, z ranges from 0.62 to 0.8, t ranges from 0.62 to 0.8, and y ranges from 0.4 to 0.6.

9. The quantum dot according to claim 8, wherein the structural composition of the quantum dot is ZnₓCd₍₁₋ₓ₎A/ZnR/ZnₜCd₍₁₋ₜ₎D/Zn_{y}Cd_{(1-y)}E/ZnG, where t ranges from 0.75 to 0.8; or the structural composition of the quantum dot is ZnₓCd₍₁₋ₓ₎A/Zn_{z}Cd_{(1-z)}R/ZnD/Zn_{y}Cd_{(1-y)}E/ZnG, where z ranges from 0.62 to 0.7; or the structural composition of the quantum dot is ZnₓCd₍₁₋ₓ₎A/Zn_{z}Cd_{(1-z)}R/ZnₜCd₍₁₋ₜ₎D/Zn_{y}Cd_{(1-y)}E/ZnG, where z ranges from 0.75 to 0.8 and t ranges from 0.62 to 0.7.

10. The quantum dot according to claim 2, wherein an average particle size of the quantum dot ranges from 6 nm to 10 nm, an average particle size of the core of the quantum dot ranges from 3 nm to 4.5 nm, an average thickness of the first shell layer ranges from 0.8 nm to 1.5 nm, an average thickness of the second shell layer ranges from 0.3 nm to 0.5 nm, and an average thickness of the third shell layer ranges from 1.1 nm to 2 nm.

11. A method for preparing a quantum dot comprising:
S1. providing a cationic precursor which is a solution comprising a zinc source and a cadmium source, introducing an inert gas at room temperature to expel air, and heating the cationic precursor to a temperature ranged between 125° C. and 180° C. for 30 minutes˜90 minutes to obtain a basic solution, after the air is completely expelled;
S2. heating the basic solution to a reaction temperature, injecting an anionic precursor into the basic solution, and ripening to obtain a core;
S3. forming multiple shell layers sequentially on a surface of the core to obtain a reaction liquid comprising the quantum dot;
wherein the quantum dot with a core-shell structure, and in a direction of the core of the quantum dot towards an outermost shell layer of the quantum dot, mole percentages of cadmium in the core and shell layers comprising cadmium gradually increase.

12. The method according to claim 11, wherein a molar ratio of zinc to cadmium in the cationic precursor is 100:(5˜20), and a concentration of zinc in the cationic precursor ranges from 0.05 mol/L to 1 mol/L.

13. The method according to claim 11, wherein the anionic precursor is one or more of a selenium precursor and a sulfur precursor, and a molar ratio of anions in the anion precursor injected into the basic solution to cadmium ions in the basic solution is 10:(0.5˜8).

14. The method according to claim 11, wherein the reaction temperature ranges from 250° C. to 315° C., and the ripening time ranges from 10 minutes to 60 minutes.

15. The method according to claim 11, wherein for the quantum dot obtained by the S3, a molar ratio of anions in the shell layers to anions in the core is 1:(0.5˜3).

16. A photoelectric device comprising:
an anode;
a cathode; and
multiple functional layers disposed between the anode and the cathode, wherein a material of one of the multiple functional layers comprises a quantum dot with a core-shell structure;
wherein in a direction of a core of the quantum dot towards an outermost shell layer of the quantum dot, mole percentages of cadmium in the core and shell layers comprising cadmium gradually increase.

17. The photoelectric device according to claim 16, wherein the functional layers comprise an active layer, and a material of the active layer comprises the quantum dot.

18. The photoelectric device according to claim 17, wherein the active layer is a light emitting layer or a light absorbing layer.

19. The photoelectric device according to claim 17, wherein the functional layers further comprise an electron functional layer disposed between the active layer and the cathode, and a material of the electron functional layer is selected from one or more of an undoped-type first inorganic compound and a doped-type second inorganic compound;
wherein the undoped-type first inorganic compound comprises one or more of an undoped-type first metal oxide, a group IIB-VIA semiconductor material, a group IIIA-VA semiconductor material, and a group IB-IIIA-VIA semiconductor material; the undoped-type first metal oxide comprises one or more of ZnO, TiO₂, SnO₂, BaO, Ta₂O₃, Al₂O₃, and ZrO₂; the group IIB-VIA semiconductor material comprises one or more of ZnS, ZnSe, and CdS; the group IIIA-VA semiconductor material comprises one or more of InP and GaP; the group IB-IIIA-VIA semiconductor material comprises one or more of CuInS and CuGaS; and
the doped-type second inorganic compound comprises a doped-type second metal oxide, a host metal oxide of the doped-type second metal oxide is selected from ZnO, TiO₂, SnO₂, BaO, Ta₂O₃, Al₂O₃, or ZrO₂, and a doping element of the doped second metal oxide is selected from one or more of Mg, Ca, Zr, W, Ga, Li, Al, Ti, Y, In, and Sn.

20. The photoelectric device according to claim 17, wherein the functional layers further comprise a hole functional layer disposed between the active layer and the anode, and a material of the hole functional layer is selected from one or more of an undoped-type third inorganic compound, a doped-type fourth inorganic compound, and an organic compound;
wherein the organic compound is selected from one or more of poly(3,4-ethylenedioxythiophene)-poly(styrenesulfonate), copper(II) phthalocyanine, titanyl phthalocyanine, 2,3,5,6-tetrafluoro-7,7,8,8-tetracyanoquinodimethane, hexaazatriphenylenehexacabonitrile, polyaniline, polypyrrole, poly(3-hexylthiophene-2,5-diyl), poly(n-vinylcarbazole), 4,4′-Bis(N-carbazolyl)-1,1′-biphenyl, poly[N,N′-bis(4-butylphenyl)-N,N′-bis(phenyl)-benzi, 4,4′-cyclohexylidenebis[N,N-bis(4-methylphenyl)aniline], poly(9,9-dioctylfluorene-co-N-(4-butylphenyl)diphenylamine), poly[(9,9-dioctylfluorenyl-2,7-diyl)-alt-(4,4′-(N-(4-butylphenyl), 4,4′,4″-tris(N-3-methylphenyl-N-phenylamino)triphenylamine, 4,4′,4″-tris(carbazol-9-yl)-triphenylamine, 4,4′,4″-tris[2-naphthyl(phenyl)amino]triphenylamine, N,N′-bis-(1-naphthalenyl)-N,N′-bis-phenyl-(1,1′-biphenyl)-4,4′-diamine, N,N′-bis(3-methylphenyl)-N,N′-diphenyl-benzidine, N,N′-bis[4-(diphenylamino)phenyl]-N,N′-diphenylbenzidine, N2,N7-diphenyl-N2,N7-di-m-tolyl-9,9′-spirobi[fluorene]-2,7-diamine, N2,N7-di-1-naphthalenyl-N2,N7-diphenyl-9,9′-spirobi[9h-fluorene]-2,7-diamine, poly[bis(4-phenyl)(2,4,6-trimethylphenyl)amine], and 2,2′,7,7′-Tetrakis[N,N-di(4-methoxyphenyl)amino]-9,9′-spirobifluorene; and
the undoped-type third inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, and tungsten sulphide; and
a host inorganic compound of the doped-type fourth inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, and tungsten sulphide, and a doping element of the doped-type fourth inorganic compound is selected from one or more of nickel, molybdenum, tungsten, vanadium, chromium, copper and platinum group metal elements, and a mole percentage of the doping element is not more than 50%.
